(19) United States
(12) Patent Application Publication
(10) Pub. No.: US 2009/0117699 A1
(43) Pub. Date: May 7, 2009

(54) METHOD FOR PREPARING A RECESSED TRANSISTOR STRUCTURE

(75) Inventor: HUNG YANG LIN, TAIPEI COUNTY (TW)

Correspondence Address: WPAT, PC;INTELLECTUAL PROPERTY ATTORNEYS, 2030 MAIN STREET, SUITE 1300, IRVINE, CA, 92614, US

(73) Assignee: PROMOS TECHNOLOGIES INC., HSINCHU (TW)

(21) Appl. No.: 12/033,400

(22) Filed: Feb. 19, 2008

(30) Foreign Application Priority Data
Nov. 2, 2007 (TW) 096141269

(51) Int. Cl. H01L 21/336

(52) U.S. Cl. 438/270; 257/E21.419

(57) ABSTRACT

A method for preparing a recessed transistor structure comprises the steps of performing an implanting process to form a doped layer in a substrate, forming a plurality of gate-isolation blocks on the substrate, forming a plurality of first spacers on sidewalls of the gate-isolation blocks, removing a portion of the substrate not covered by the first spacers and the gate-isolation blocks to form a plurality of depressions in the substrate between the first spacers, forming a gate oxide layer on inner sidewalls of the depressions, and forming a gate structure on the gate oxide layer to complete the recessed transistor structure.

### BACKGROUND OF THE INVENTION

(A) Field of the Invention

The present invention relates to a method for preparing a recessed transistor structure, and more particularly, to a method for preparing a recessed transistor structure with a damascene gate and without misalignment problems.

(B) Description of the Related Art

FIG. 1 to FIG. 6 illustrate a method for preparing a recessed transistor structure 10 according to the prior art. The conventional method first uses the deposition technique to form a silicon oxide layer 14 on a silicon substrate 12 and a polysilicon layer 16 on the silicon oxide layer 14. A first photolithographic process is then performed to form a photoresist layer 18 having a plurality of openings 20 on the polysilicon layer 16. Subsequently, a dry etching process is performed by using the photoresist layer 16 as an etching mask to remove a portion of the polysilicon layer 16 under the openings 20, and the remaining polysilicon layer 16 and the silicon oxide layer 14 are used as an etching mask 14′ to remove the silicon substrate 12 not covered by the etching mask 14′ to form a plurality of concavities 22 in the silicon substrate 12, as shown in FIG. 2.

Referring to FIG. 3, a wet etching process is performed to remove the etching mask 14′, and a thermal oxidation process is then performed to form a gate oxide layer 24 on the surface of the silicon substrate 12 and the inner sidewall of the concavities 22. Subsequently, the chemical vapor phase deposition process is performed to form a conductive structure 26 filling the concavities 22 and a silicon nitride layer 28 on the conductive structure 26, and a second photolithographic process is then performed to form a photoresist layer 30 having a plurality of openings 32 on the silicon nitride layer 28, as shown in FIG. 4.

Referring to FIG. 5, the dry etching process is performed to remove a portion of the silicon nitride layer 28 and the conductive structure 26 under the openings 32 to form a plurality of gate structures 26′, an implanting process is then performed to form a plurality of doped regions 12′ in the silicon substrate 12, and a spacer is formed on the sidewall of the gate structures 26′. Subsequently, the chemical vapor phase deposition process is performed to form a barrier layer 36 and an insulation layer 38 to complete the recessed transistor structure 10, as shown in FIG. 6.

According to the prior art, the gate structures 26′ are formed before the spacer 34, the barrier layer 34 and the insulation layer 38 to electrically isolate the gate structures 26′. In addition, the prior art needs to perform the photolithographic process twice for patterning the concavities 22 and the gate structures 26′, which can easily cause the recessed transistor structure 10 to fail due to misalignment.

### SUMMARY OF THE INVENTION

One aspect of the present invention provides a method for preparing a recessed transistor structure with a damascene gate, which uses a single photolithographic process to pattern the gate so as to avoid misalignment problems due to using two photolithographic processes.

A method for preparing a recessed transistor structure according to this aspect of the present invention comprises the steps of performing an implanting process to form a doped layer in a substrate, forming a plurality of gate-isolation blocks on the substrate, forming a plurality of first spacers on sidewalls of the gate-isolation blocks, removing a portion of the substrate not covered by the first spacers and the gate-isolation blocks to form a plurality of depressions in the substrate between the first spacers, forming a gate oxide layer on inner sidewalls of the depressions, and forming a gate structure on the gate oxide layer.

The conventional method forms the gate structures before the spacer, the barrier layer and the insulation layer to electrically isolate the gate structures. In contrast, the present method forms the gate structures after the spacer structure and the gate-isolation blocks to electrically isolate the gate structures

In addition, the prior art needs to perform the photolithographic process twice for patterning the concavities and the gate structures, which can easily cause the recessed transistor structure to fail due to misalignment. In contrast, the present method uses a single photolithographic process to pattern the gate-isolation blocks, which can avoid the failure due to misalignment since only one photolithographic process is used.

### BRIEF DESCRIPTION OF THE DRAWINGS

The objectives and advantages of the present invention will become apparent upon reading the following description and upon reference to the accompanying drawings in which:

FIG. 1 to FIG. 6 illustrate a method for preparing a recessed transistor structure according to the prior art; and

FIG. 7 to FIG. 17 illustrate a method for preparing a recessed transistor structure according to the present invention.

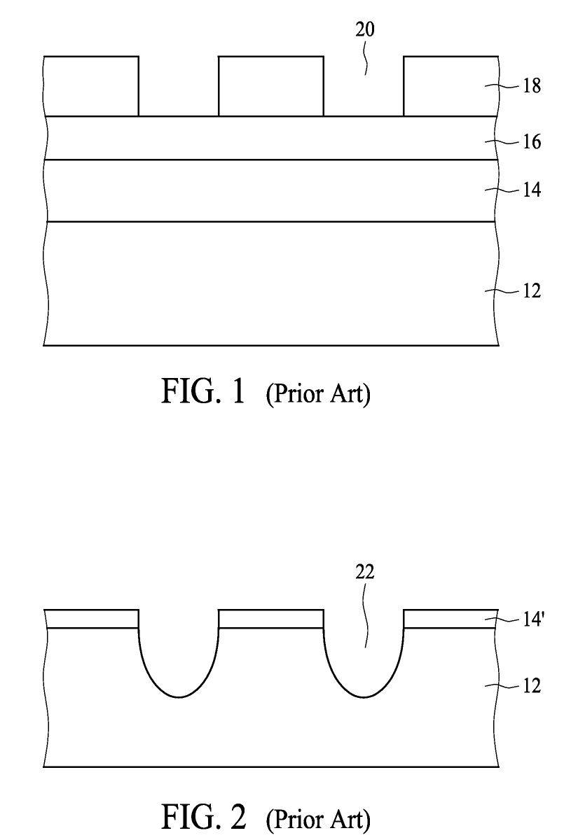

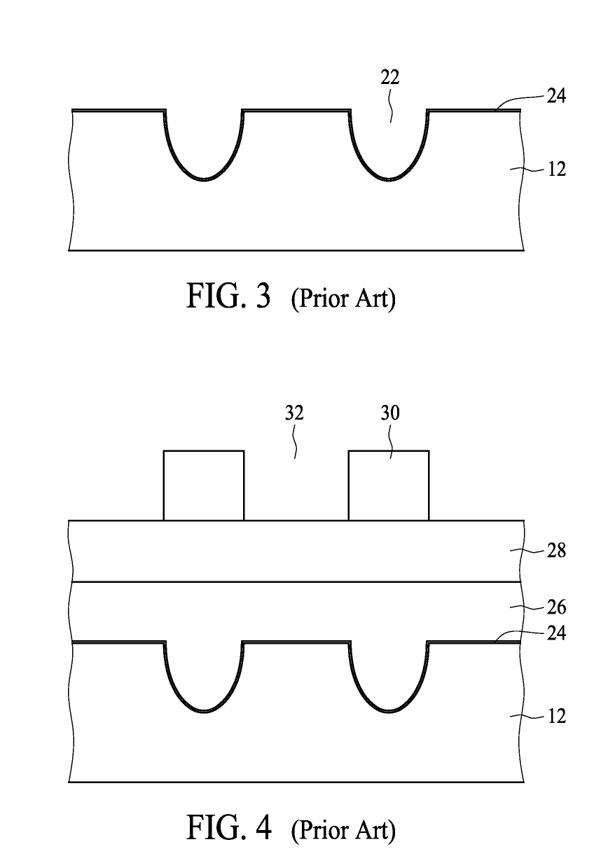

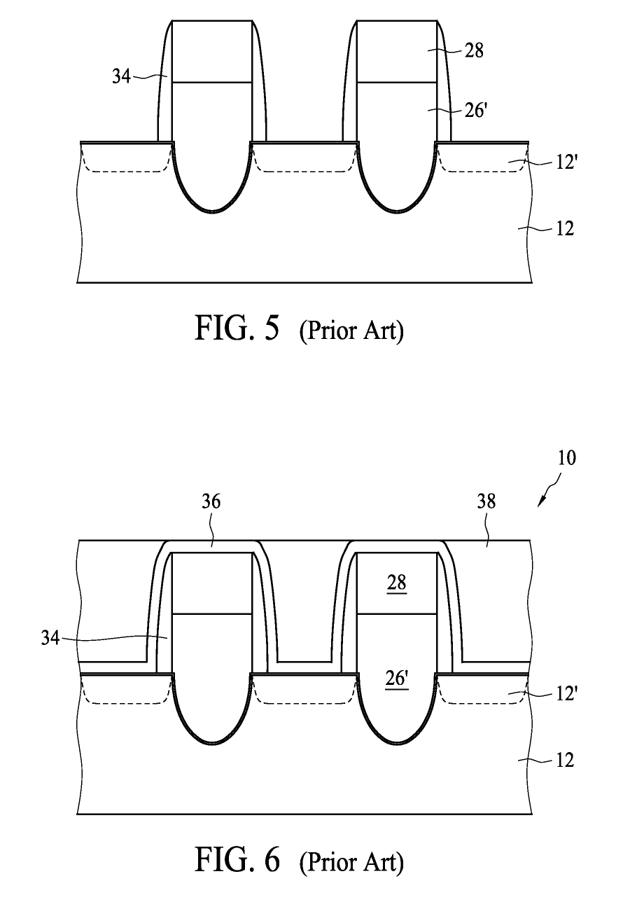

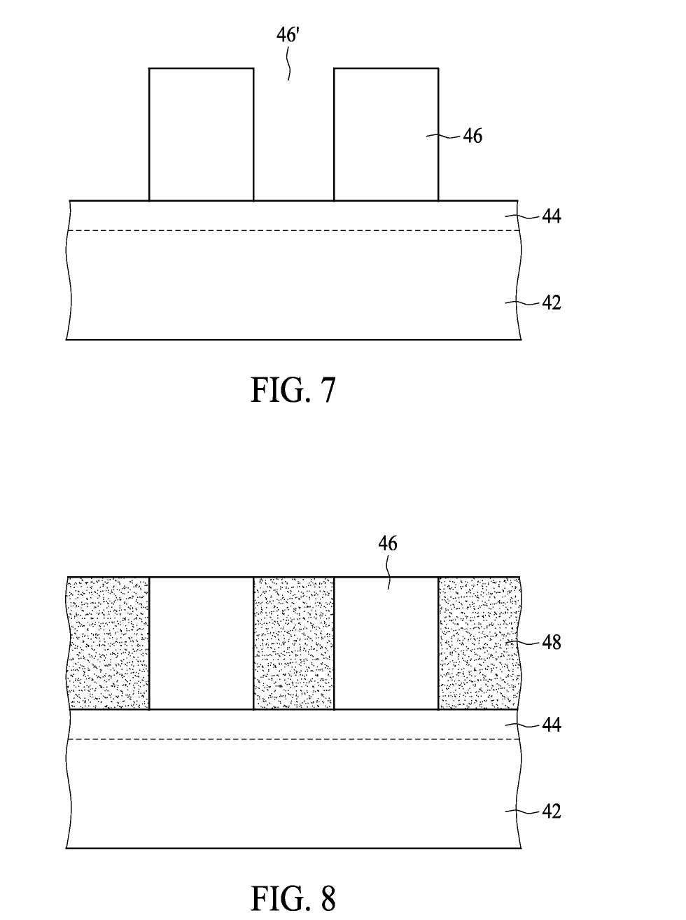

### DETAILED DESCRIPTION OF THE INVENTION

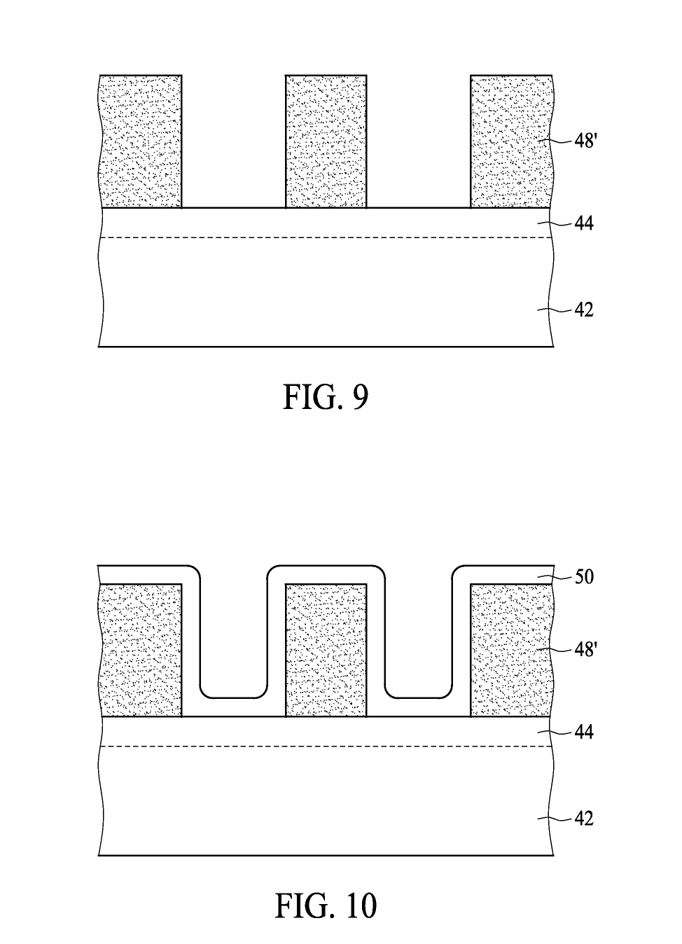

FIG. 7 to FIG. 17 illustrate a method for preparing a recessed transistor structure 40 according to the present invention. First, an implanting process is performed to form a doped layer 44 in an upper portion of a silicon substrate 42, and a photolithographic process is then performed to form a photoresist layer having a plurality of openings 46′ on the silicon substrate 42. Subsequently, a selective liquid-phase deposition process is performed to form an insulation layer 48 filling the openings 46′, as shown in FIG. 8. In particular, the selective liquid-phase deposition process selectively forms the insulation layer 48 only on the surface of the silicon substrate 42, not on the surface of the photoresist layer 46.

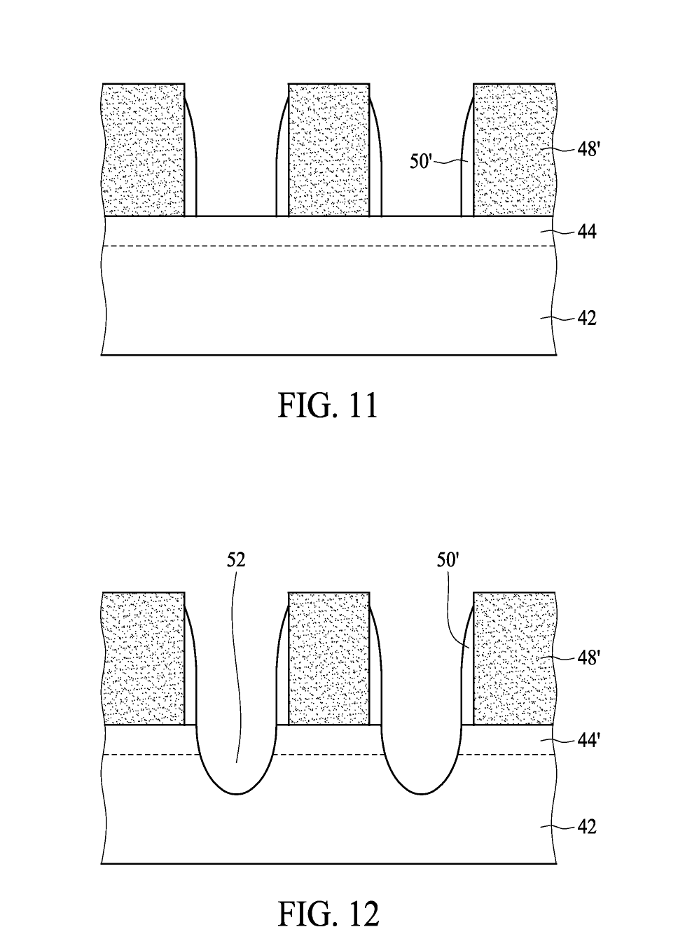

Referring to FIG. 9, after removing the photoresist layer 46, a thermal treating process is performed to solidify the insulation layer 48 such that the insulation layer 48 filling the openings 46′ forms a plurality of gate-isolation blocks 48′. Preferably, the insulation layer 48 includes silicon oxide, and the thermal treating process is performed at a temperature between 850° C. and 1150° C. Subsequently, the chemical vapor phase deposition process is used to form a dielectric layer 50 covering the gate-isolation blocks 48′ and the silicon substrate 42, as shown in FIG. 10. Preferably, the dielectric layer 50 includes silicon nitride.

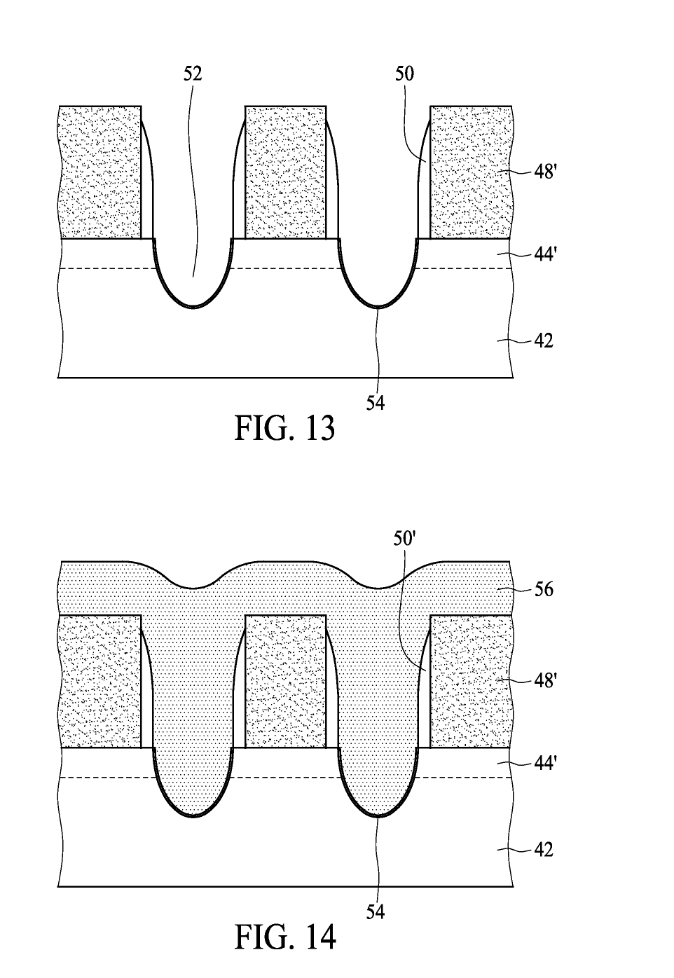

Referring to FIG. 11, an anisotropic dry etching process is performed to remove a portion of the dielectric layer 50 to form a plurality of first spacers 50′ having a vertical surface facing the gate-isolation blocks 48′. Subsequently, another anisotropic dry etching process is performed to remove a portion of the silicon substrate 42 not covered by the first spacers 50′ and the gate-isolation blocks 48′ to form a plurality of depressions 52 in the silicon substrate 42 between the first spacers 50′, as shown in FIG. 12. In particular, the anisotropic dry etching process forming the depressions 52 in the silicon substrate 42 between the first spacers 50′ also segments the doped layer 44 into a plurality of self-aligned doped regions 44′ serving as sources/drains of the recessed transistor structure 40.

Referring to FIG. 13, an implanting process is performed to adjust the resistance of the silicon substrate 42 below the depressions 52, and a thermal oxidation process is then performed to form a gate oxide layer 54 on the inner sidewalls of the depressions 54. The silicon substrate 42 below the depressions 52 serves as the carrier channel of the recessed transistor structure 40. Subsequently, the chemical vapor phase deposition process is used to form a doped polysilicon layer 56 filling the depressions 52 and covering the first spacers 50 and the gate-isolation blocks 48′, as shown in FIG. 14.

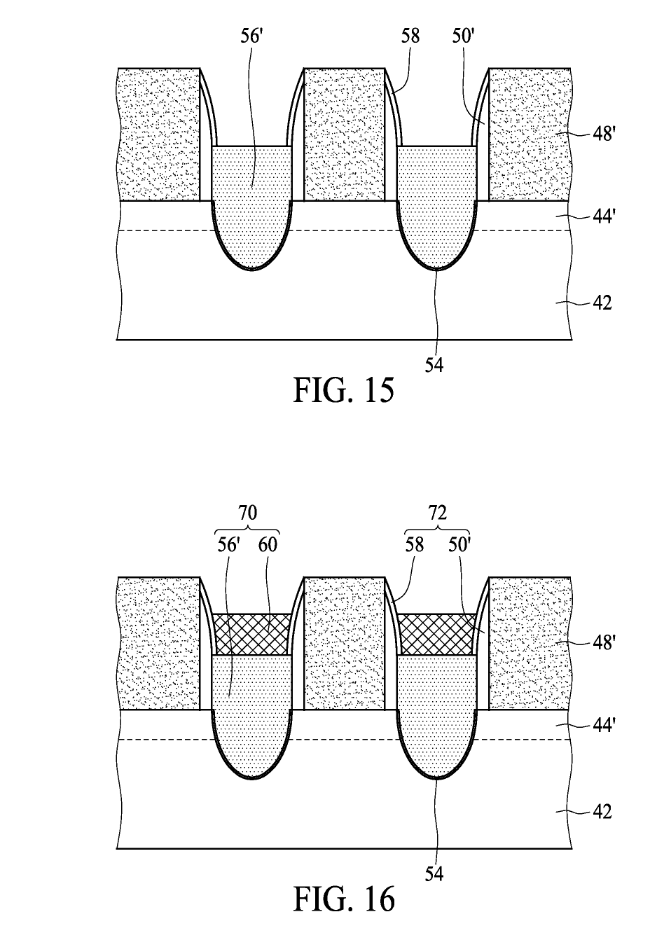

Referring to FIG. 15, a chemical-mechanical polishing process is performed by using the surface of the gate-isolation blocks 48′ as the polishing end point to remove a portion of the doped polysilicon layer 56, and the anisotropic dry etching process is used to remove a portion of the doped polysilicon layer 56 between the gate-isolation blocks 48′ to form a plurality of conductive blocks 56′ filling the depressions 52. Subsequently, a plurality of second spacers 58 are formed on the conductive blocks 56′, i.e., on the sidewalls of the first spacers 50′, and a metal silicide layer 60 such as a tungsten silicide layer is formed on the conductive blocks 56′, as shown in FIG. 16.

In particular, the preparation of the second spacers 58 is similar to that of the first spacers 50′, and the preparation of the metal silicide layer 60 is similar to that of the conductive blocks 56′. In addition, the conductive blocks 56′ and the metal silicide layer 60 together form a plurality of gate structures 70 of the recessed transistor structure 40. The first spacers 50′ and the second spacers 58 together form a plurality of spacer structures 72 having a vertical surface facing the gate-isolation blocks 48′ and a curve surface facing the gate structures 70.

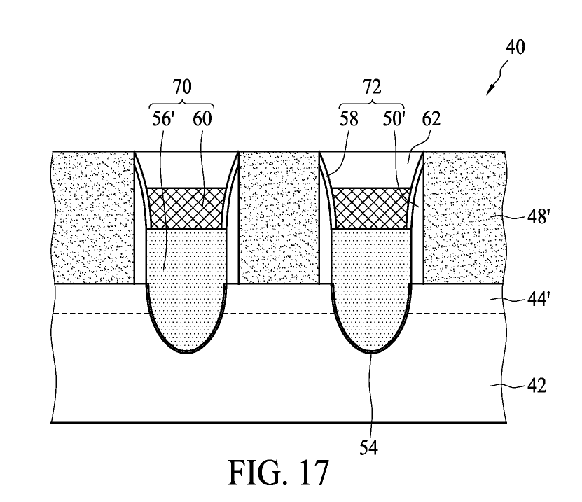

Referring to FIG. 17, the chemical vapor phase deposition process is used to form a cap layer 62 including silicon nitride and covering the gate structure 70 and the gate-isolation blocks 48′. Subsequently, the chemical-mechanical polishing process is used to remove a portion of the silicon nitride layer 62 above the gate-isolation blocks 48′, using the surface of the gate-isolation blocks 48′ as the polishing end point, to complete the recessed transistor structure 40. In particular, the spacer structure 72 has the curve surface facing the gate structure 70 set within the spacer structure 72. Therefore, the metal silicide layer 60 of the gate structure 70 has a profile with larger width at the upper portion than at the lower portion, and the width of the metal silicide layer 60 at the bottom portion is smaller than that of the conductive blocks 56′ at the upper portion. Similarly, the cap layer 62 also has a profile with larger width at the upper portion than at the lower portion.

The conventional method forms the gate structures 26′ before the spacer 34, the barrier layer 36 and the insulation layer 38 for electrically isolating the gate structures 26′. In contrast, after forming the spacer structures 72 and the gate-isolation blocks 48′ for electrically isolating the gate structures 70, the gate structures 70 set within the spacer structures 72 are formed.

In addition, the prior art needs to perform the photolithographic process twice for patterning the concavities 22 and the gate structures 26′, which can easily cause the recessed transistor structure 40 to fail due to misalignment. In contrast, the present method uses a single photolithographic process to pattern the gate-isolation blocks 48′, which can avoid such failure due to misalignment since only one photolithographic process is used.

The above-described embodiments of the present invention are intended to be illustrative only. Numerous alternative embodiments may be devised by those skilled in the art without departing from the scope of the following claims.

What is claimed is:

1. A method for preparing a recessed transistor structure, comprising the steps of:
performing an implanting process to form a doped layer in a substrate;
forming a plurality of gate-isolation blocks on the substrate;
forming a plurality of first spacers on sidewalls of the gate-isolation blocks;
removing a portion of the substrate not covered by the first spacers and the gate-isolation blocks to form a plurality of depressions in the substrate between the first spacers;
forming a gate oxide layer on inner sidewalls of the depressions; and
forming a gate structure on the gate oxide layer.

2. The method for preparing a recessed transistor structure of claim 1, wherein the step of forming a plurality of gate-isolation blocks on the substrate includes:
forming a photoresist layer having a plurality of openings on the substrate;
performing a deposition process to form an insulation layer filling the openings; and
removing the photoresist layer such that the insulation layer filling the openings forms the gate-isolation blocks.

3. The method for preparing a recessed transistor structure of claim 2, wherein the deposition process is a selective liquid-phase deposition process.

4. The method for preparing a recessed transistor structure of claim 3, wherein the selective liquid-phase deposition process selectively forms the insulation layer on the surface of the substrate.

5. The method for preparing a recessed transistor structure of claim 2, further comprising a step of performing a thermal treating process to solidify the insulation layer.

6. The method for preparing a recessed transistor structure of claim 5, wherein the thermal treating process is performed at a temperature between 850° C. and 1150° C.

7. The method for preparing a recessed transistor structure of claim 1, wherein the step of removing a portion of the substrate not covered by the first spacers and the gate-isolation blocks to form a plurality of depressions in the substrate between the first spacers is performing an etching process to segment the doped layer into a plurality of self-aligned source/drain doped regions.

8. The method for preparing a recessed transistor structure of claim 1, wherein the step of forming a gate structure on the gate oxide layer includes:
forming a plurality of conductive blocks filling the depressions; and
forming a metal silicide layer on the conductive blocks.

9. The method for preparing a recessed transistor structure of claim 8, wherein the step of forming a plurality of conductive blocks filling the depressions includes:
performing a chemical vapor phase deposition process to form a doped polysilicon layer filling the depressions and covering the first spacers and the gate-isolation blocks;
removing a portion of the doped polysilicon layer on the gate-isolation blocks; and
performing an anisotropic dry etching process to remove a portion of the doped polysilicon layer between the gate-isolation blocks to form the conductive blocks filling the depressions.

10. The method for preparing a recessed transistor structure of claim 9, wherein the step of removing a portion of the doped polysilicon layer on the gate-isolation blocks is performing a chemical-mechanical polishing process.

11. The method for preparing a recessed transistor structure of claim 10, wherein the chemical-mechanical polishing process uses the surface of the gate-isolation blocks as a polishing end point.

12. The method for preparing a recessed transistor structure of claim 8, further comprising a step of forming a plurality of second spacers on the conductive blocks before forming a metal silicide layer on the conductive blocks.

13. The method for preparing a recessed transistor structure of claim 1, wherein the step of forming a plurality of first spacers on sidewalls of the gate-isolation blocks includes:
forming a dielectric layer covering the gate-isolation blocks and the substrate; and
performing an etching process to remove a portion of the dielectric layer to form the first spacers having a curve surface facing the gate structure.

14. The method for preparing a recessed transistor structure of claim 1, further comprising a step of forming a cap layer covering the gate structure.

15. The method for preparing a recessed transistor structure of claim 14, wherein the step of forming a cap layer covering the gate structure includes:
forming a silicon nitride layer covering the gate structure and the gate-isolation blocks; and
performing a chemical-mechanical polishing process to remove a portion of the silicon nitride layer above the gate-isolation blocks.

16. The method for preparing a recessed transistor structure of claim 15, wherein the chemical-mechanical polishing process uses the surface of the gate-isolation blocks as a polishing end point.
